(19) United States
(12) Patent Application Publication
(10) Pub. No.: US 2026/0255662 A1
(43) Pub. Date: Aug. 27, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Shunsuke ASABA, Himeji Hyogo (JP); Kyungpil NAM, Himeji Hyogo (JP); Yujiro HARA, Himeji Hyogo (JP); Hiroshi KONO, Himeji Hyogo (JP)

(21) Appl. No.: 19/392,608

(22) Filed: Nov. 18, 2025

(30) Foreign Application Priority Data
Feb. 26, 2025 (JP) 2025-028904

(51) Int. Cl. H10D 84/00

(52) U.S. Cl. CPC H10D 84/146

(57) ABSTRACT

A semiconductor device of embodiments includes: a first transistor region including at least one transistor unit; a second transistor region including at least one transistor unit and provided in a first direction with respect to the first transistor region; a first diode region provided between the first transistor region and the second transistor region and including at least one diode unit; a second diode region provided between the first diode region and the second transistor region and including at least one diode unit; and a third transistor region provided between the first diode region and the second diode region and including one transistor unit.

### CROSS-REFERENCE TO RELATED APPLICATION

This application is based upon and claims the benefit of priority from Japanese Patent Application No. 2025-028904, filed on February 26, 2025, the entire contents of which are incorporated herein by reference.

### FIELD

Embodiments described herein relate generally to a semiconductor device.

### BACKGROUND

A vertical metal oxide semiconductor field effect transistor (MOSFET) using silicon carbide has a pn junction diode as a built-in diode. For example, the MOSFET is used as a switching element connected to an inductive load. In this case, even when the MOSFET is off, a freewheeling current can be made to flow by using a built-in diode.

However, when a freewheeling current is made to flow by using a body diode, a stacking fault grows in a silicon carbide layer due to the recombination energy of carriers, which causes a problem of increasing the on-resistance of the MOSFET. The increase in the on-resistance of a MOSFET leads to a reduction in the reliability of the MOSFET. For example, by providing a Schottky barrier diode (SBD) operating in a unipolar manner in the MOSFET as a built-in diode, it is possible to suppress the growth of a stacking fault in the silicon carbide layer. The reliability of the MOSFET is improved by providing the SBD as a built-in diode in the MOSFET.

A large surge current may flow through the MOSFET, exceeding the steady state instantaneously. When a large surge current flows, a high surge voltage is applied to generate heat, and as a result, the MOSFET breaks down. The maximum allowable peak current value (I_{FSM}) of the surge current allowed in the MOSFET is referred to as a surge current withstand capacity. In a MOSFET in which the SBD is provided, it is desired to improve the surge current withstand capacity.

For example, in order to allow a large surge current to flow, it is conceivable to provide a diode region, which includes a pn junction diode and does not operate as a transistor, in the MOSFET. However, providing the diode region that does not operate as a transistor may increase the on-resistance per unit area of the MOSFET.

### BRIEF DESCRIPTION OF THE DRAWINGS

FIG. 1 is a schematic top view of a semiconductor device according to a first embodiment;

FIG. 2 is a schematic top view of a part of the semiconductor device according to the first embodiment;

FIG. 3 is a schematic cross-sectional view of a part of the semiconductor device according to the first embodiment;

FIG. 4 is a schematic top view of a part of the semiconductor device according to the first embodiment;

FIG. 5 is a schematic cross-sectional view of a part of the semiconductor device according to the first embodiment;

FIG. 6 is a schematic cross-sectional view of a part of the semiconductor device according to the first embodiment;

FIG. 7 is an equivalent circuit diagram of the semiconductor device according to the first embodiment;

FIG. 8 is an explanatory diagram of the function and effect of the semiconductor device according to the first embodiment;

FIG. 9 is an explanatory diagram of the function and effect of the semiconductor device according to the first embodiment;

FIG. 10 is a schematic top view of a part of a semiconductor device according to a comparative example;

FIG. 11 is a schematic cross-sectional view of a part of the semiconductor device according to the comparative example;

FIG. 12 is a diagram showing a problem of the semiconductor device according to the comparative example;

FIG. 13 is an explanatory diagram of the function and effect of the semiconductor device according to the first embodiment;

FIG. 14 is a schematic top view of a part of a semiconductor device according to a first modification example of the first embodiment;

FIG. 15 is a schematic cross-sectional view of a part of the semiconductor device according to the first modification example of the first embodiment;

FIG. 16 is a schematic top view of a part of a semiconductor device according to a second modification example of the first embodiment;

FIG. 17 is a schematic cross-sectional view of a part of a semiconductor device according to a second embodiment;

FIG. 18 is a schematic cross-sectional view of a part of the semiconductor device according to the second embodiment;

FIG. 19 is a schematic cross-sectional view of a part of a semiconductor device according to a third embodiment;

FIG. 20 is a schematic cross-sectional view of a part of the semiconductor device according to the third embodiment; and

FIG. 21 is a schematic cross-sectional view of a part of a semiconductor device according to a fourth embodiment.

### DETAILED DESCRIPTION

A semiconductor device of embodiments includes: a first transistor region including at least one transistor unit; a second transistor region including at least the one transistor unit and provided in a first direction with respect to the first transistor region; a first diode region provided between the first transistor region and the second transistor region and including at least one diode unit; a second diode region provided between the first diode region and the second transistor region and including at least the one diode unit; and a third transistor region provided between the first diode region and the second diode region and including the one transistor unit. The transistor unit includes: a first electrode; a second electrode; a first silicon carbide region of a first conductive type provided between the first electrode and the second electrode and including a first portion in contact with the first electrode and extending in a second direction perpendicular to the first direction and a second portion in contact with the first electrode, provided in the first direction with respect to the first portion, and extending in the second direction; a second silicon carbide region of a second conductive type provided between the first silicon carbide region and the first electrode, electrically connected to the first electrode, extending in the second direction, and provided between the first portion and the second portion in the first direction; a third silicon carbide region of a second conductive type provided between the first silicon carbide region and the first electrode, electrically connected to the first electrode, extending in the second direction, provided between the second silicon carbide region and the second portion in the first direction, and spaced from the second silicon carbide region; a fourth silicon carbide region of a first conductive type provided between the second silicon carbide region and the first electrode and electrically connected to the first electrode; a first gate electrode facing the second silicon carbide region and the third silicon carbide region and extending in the second direction; and a gate insulating layer provided between the first gate electrode and each of the second silicon carbide region and the third silicon carbide region. The diode unit includes: the first electrode; the second electrode; the first silicon carbide region including a third portion in contact with the first electrode and extending in the second direction and a fourth portion in contact with the first electrode, provided in the first direction with respect to the third portion, and extending in the second direction; and a fifth silicon carbide region of a second conductive type provided between the first silicon carbide region and the first electrode, electrically connected to the first electrode, extending in the second direction, and continuously provided between the third portion and the fourth portion in the first direction. A first distance between the first portion and the second portion in the first direction is equal to a second distance between the third portion and the fourth portion in the first direction.

Hereinafter, embodiments will be described with reference to the diagrams. In addition, in the following description, the same or similar members and the like may be denoted by the same reference numerals, and the description of the members and the like once described may be omitted as appropriate.

In addition, in the following description, the notations of n⁺, n, n⁻, p⁺, p, and p⁻ indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, distances such as the depth and thickness of the impurity region can be calculated by using, for example, an image obtained using a scanning electron microscope (SEM) or by SIMS.

In this specification, the impurity concentration of a semiconductor region means the maximum impurity concentration of the semiconductor region, unless otherwise specified.

### First Embodiment

A semiconductor device according to a first embodiment includes: a first transistor region including at least one transistor unit; a second transistor region including at least the one transistor unit and provided in a first direction with respect to the first transistor region; a first diode region provided between the first transistor region and the second transistor region and including at least one diode unit; a second diode region provided between the first diode region and the second transistor region and including at least the one diode unit; and a third transistor region provided between the first diode region and the second diode region and including the one transistor unit. The transistor unit includes: a first electrode; a second electrode; a first silicon carbide region of a first conductive type provided between the first electrode and the second electrode and including a first portion in contact with the first electrode and extending in a second direction perpendicular to the first direction and a second portion in contact with the first electrode, provided in the first direction with respect to the first portion, and extending in the second direction; a second silicon carbide region of a second conductive type provided between the first silicon carbide region and the first electrode, electrically connected to the first electrode, extending in the second direction, and provided between the first portion and the second portion in the first direction; a third silicon carbide region of a second conductive type provided between the first silicon carbide region and the first electrode, electrically connected to the first electrode, extending in the second direction, provided between the second silicon carbide region and the second portion in the first direction, and spaced from the second silicon carbide region; a fourth silicon carbide region of a first conductive type provided between the second silicon carbide region and the first electrode and electrically connected to the first electrode; a first gate electrode facing the second silicon carbide region and the third silicon carbide region and extending in the second direction; and a gate insulating layer provided between the first gate electrode and each of the second silicon carbide region and the third silicon carbide region. The diode unit includes: the first electrode; the second electrode; the first silicon carbide region including a third portion in contact with the first electrode and extending in the second direction and a fourth portion in contact with the first electrode, provided in the first direction with respect to the third portion, and extending in the second direction; and a fifth silicon carbide region of a second conductive type provided between the first silicon carbide region and the first electrode, electrically connected to the first electrode, extending in the second direction, and continuously provided between the third portion and the fourth portion in the first direction. A first distance between the first portion and the second portion in the first direction is equal to a second distance between the third portion and the fourth portion in the first direction.

The semiconductor device according to the first embodiment is a planar gate type vertical MOSFET 100 using silicon carbide. The MOSFET 100 according to the first embodiment is, for example, a double implantation MOSFET (DIMOSFET) in which a base region and a source region are formed by ion implantation. In addition, the semiconductor device according to the first embodiment includes an SBD (Schottky Barrier Diode) as a built-in diode.

In the first embodiment, a case where the first conductive type is n-type and the second conductive type is p-type will be described as an example. The MOSFET 100 is a vertical n-channel MOSFET having electrons as carriers.

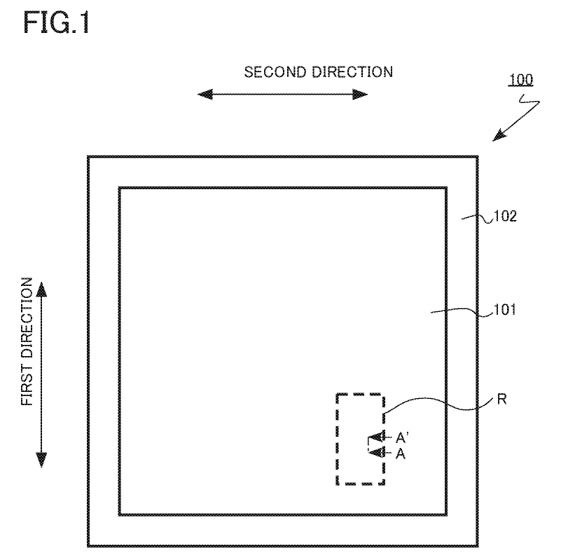

FIG. 1 is a schematic top view of the semiconductor device according to the first embodiment. FIG. 1 is a layout diagram of each region included in a MOSFET 100.

As shown in FIG. 1, the MOSFET 100 includes an element region 101 and a termination region 102. In the element region 101, a MOSFET and an SBD are provided. The termination region 102 surrounds the element region 101.

A structure for improving the breakdown voltage of the MOSFET 100 is provided in the termination region 102. The structure for improving the breakdown voltage of the MOSFET 100 is, for example, a resurf or a guard ring.

In addition, one direction parallel to the top surface of the MOSFET 100 is a first direction. In addition, a direction parallel to the top surface of the MOSFET 100 and perpendicular to the first direction is a second direction.

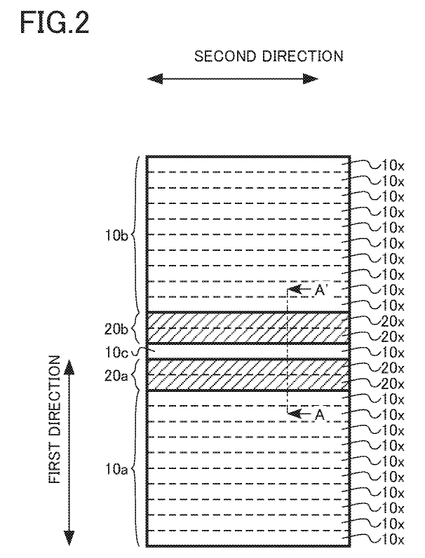

FIG. 2 is a schematic top view of a part of the semiconductor device according to the first embodiment. FIG. 2 corresponds to a region R in FIG. 1.

The MOSFET 100 includes a first transistor region 10a, a second transistor region 10b, and a third transistor region 10c. In addition, the MOSFET 100 includes a first diode region 20a and a second diode region 20b.

Hereinafter, the first transistor region 10a, the second transistor region 10b, and the third transistor region 10c may be simply referred to as the transistor region 10 either individually or collectively. In addition, the first diode region 20a and the second diode region 20b may be referred to individually or collectively as simply the diode region 20.

The transistor region 10 includes a transistor unit 10x. In addition, the diode region 20 includes a diode unit 20x.

The transistor unit 10x extends, for example, in the second direction. The transistor unit 10x is arranged, for example, in the first direction.

The diode unit 20x extends, for example, in the second direction. The diode unit 20x is arranged, for example, in the first direction.

The first transistor region 10a includes at least one transistor unit 10x. The first transistor region 10a includes, for example, a plurality of transistor units 10x.

The first transistor region 10a includes, for example, ten transistor units 10x. The number of transistor units 10x included in the first transistor region 10a is not limited to ten.

The second transistor region 10b is provided in the first direction with respect to the first transistor region 10a. The second transistor region 10b includes at least one transistor unit 10x. The second transistor region 10b includes, for example, a plurality of transistor units 10x.

The second transistor region 10b includes, for example, ten transistor units 10x. The number of transistor units 10x included in the second transistor region 10b is not limited to ten.

The first diode region 20a is provided between the first transistor region 10a and the second transistor region 10b. The first diode region 20a includes at least one diode unit 20x. The first diode region 20a includes the diode units 20x the number of which is, for example, equal to or more than two and equal to or less than ten.

The first diode region 20a includes, for example, two diode units 20x. The number of diode units 20x included in the first diode region 20a is not limited to two.

The second diode region 20b is provided between the first diode region 20a and the second transistor region 10b. The second diode region 20b includes at least one diode unit 20x. The second diode region 20b includes the diode units 20x the number of which is, for example, equal to or more than two and equal to or less than ten.

The second diode region 20b includes, for example, two diode units 20x. The number of diode units 20x included in the second diode region 20b is not limited to two.

For example, the number of diode units 20x included in the first diode region 20a is equal to the number of diode units 20x included in the second diode region 20b. In the MOSFET 100, the number of diode units 20x included in the first diode region 20a and the number of diode units 20x included in the second diode region 20b are both two, which are equal to each other.

The third transistor region 10c is provided between the first diode region 20a and the second diode region 20b. The third transistor region 10c is in contact with the first diode region 20a and the second diode region 20b. The third transistor region 10c includes one transistor unit 10x. The third transistor region 10c does not include the transistor units 10x the number of which is equal to or more than two. The third transistor region 10c includes only one transistor unit 10x.

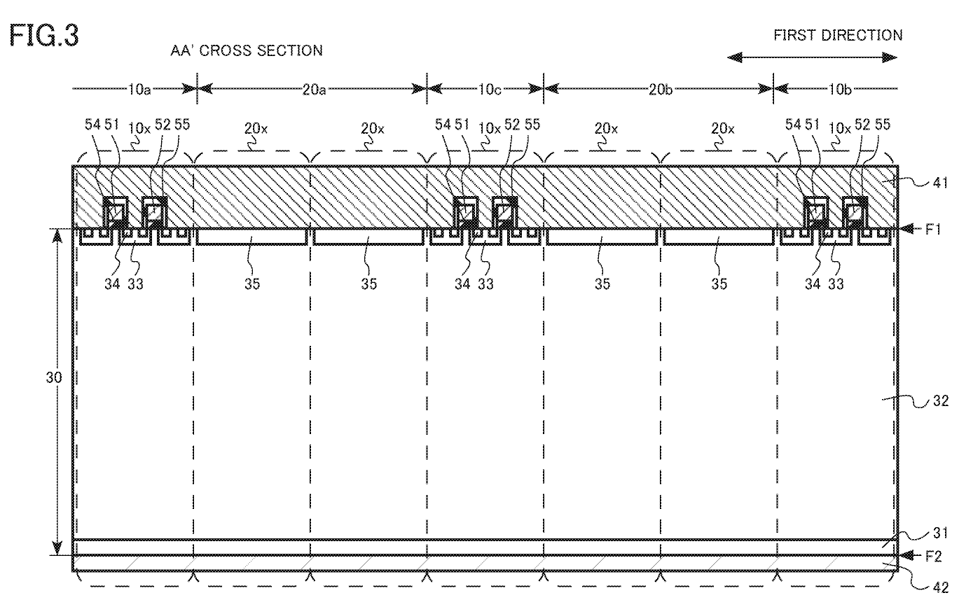

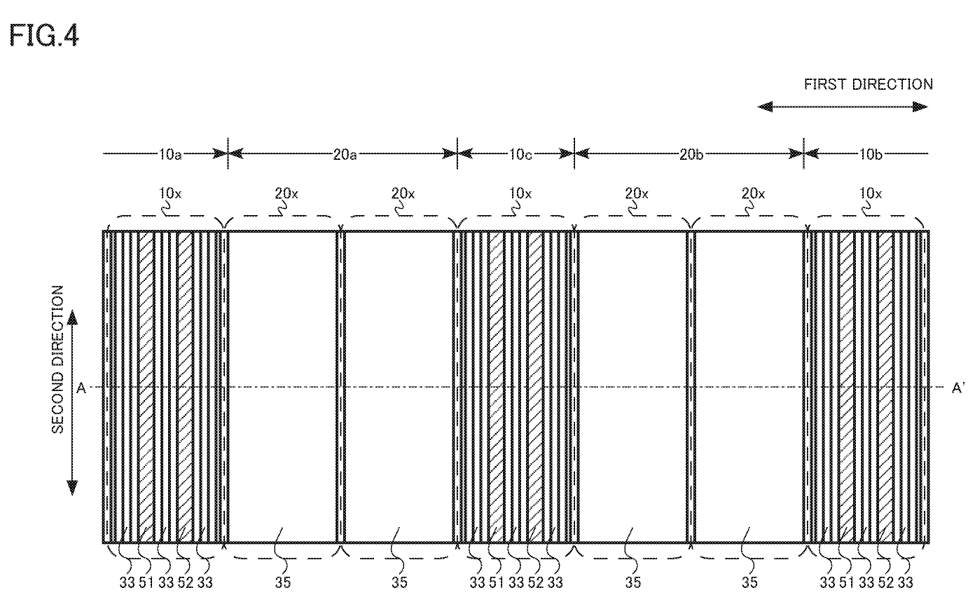

FIG. 3 is a schematic cross-sectional view of a part of the semiconductor device according to the first embodiment. FIG. 4 is a schematic top view of a part of the semiconductor device according to the first embodiment. FIG. 3 is a diagram showing a cross section taken along the line AA' of FIGS. 1, 2, and 4.

The MOSFET 100 includes a silicon carbide layer 30, a source electrode 41 (first electrode), a drain electrode 42 (second electrode), a first gate electrode 51, a second gate electrode 52, a gate insulating layer 54, and an interlayer insulating layer 55.

The silicon carbide layer 30 includes an n⁺-type drain region 31, an n⁻-type drift region 32 (first silicon carbide region), a p-type transistor base region 33, an n⁺-type source region 34 (fourth silicon carbide region), and a p-type diode base region 35 (fifth silicon carbide region).

The silicon carbide layer 30 is provided between the source electrode 41 and the drain electrode 42. The silicon carbide layer 30 is provided between the first gate electrode 51 and the drain electrode 42. The silicon carbide layer 30 is single crystal SiC. The silicon carbide layer 30 is, for example, 4H-SiC.

The silicon carbide layer 30 has a first face ("F1" in FIG. 3) and a second face ("F2" in FIG. 3). The first face F1 is a surface of the silicon carbide layer. The second face F2 is a back surface of the silicon carbide layer. Hereinafter, the first face F1 may be referred to as a surface, and the second face F2 may be referred to as a back surface. The first face F1 is disposed on the source electrode 41 side of the silicon carbide layer 30. In addition, the second face F2 is disposed on the drain electrode 42 side of the silicon carbide layer 30. The first face F1 and the second face F2 face each other. Hereinafter, “depth” means a depth in a direction toward the second face with the first face as a reference. “face” of the first face F1 and the second face F2 indicates, for example, an interface between a silicon carbide layer and an insulating layer or between a silicon carbide layer and a metal.

The first direction and the second direction are parallel to the first face F1.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The thickness of the silicon carbide layer 30 is, for example, equal to or more than 5 μ m and equal to or less than 350 μm.

The n⁺-type drain region 31 is provided between the source electrode 41 and the drain electrode 42. The drain region 31 is provided on the back surface side of the silicon carbide layer 30. The drain region 31 contains, for example, nitrogen (N) as an n-type impurity. The n-type impurity concentration of the drain region 31 is, for example, equal to or more than 1 × 10¹⁸ cm⁻³ and equal to or less than 1 × 10²¹ cm⁻³.

The n⁻-type drift region 32 is provided between the source electrode 41 and the drain electrode 42. The drift region 32 is provided between the drain region 31 and the source electrode 41. The drift region 32 is provided between the drain region 31 and the first face F1. The drift region 32 is provided on the drain region 31.

The drift region 32 includes a portion in contact with the first face F1. A further part of the portion of the drift region 32 in contact with the first face F1 is in contact with the source electrode 41.

The drift region 32 functions as an on-current path when the MOSFET 100 is in an on state.

The drift region 32 contains, for example, nitrogen (N) as an n-type impurity. The n-type impurity concentration of the drift region 32 is lower than the n-type impurity concentration of the drain region 31. The n-type impurity concentration of the drift region 32 is, for example, equal to or more than 4 × 10¹⁴ cm⁻³ and equal to or less than 5 × 10¹⁷ cm⁻³. The thickness of the drift region 32 is, for example, equal to or more than 3 μm and equal to or less than 100 μm.

The p-type transistor base region 33 is provided in the transistor region 10. The transistor base region 33 is provided between the drift region 32 and the source electrode 41. The transistor base region 33 is provided between the drift region 32 and the first face F1. The transistor base region 33 is provided on the drift region 32.

The transistor base region 33 extends in the second direction. The transistor base region 33 is repeatedly arranged in the first direction.

A part of the transistor base region 33 functions as a channel region of the MOSFET 100.

The transistor base region 33 contains, for example, aluminum (Al) as a p-type impurity. The p-type impurity concentration of the transistor base region 33 is, for example, equal to or more than 5 × 10¹⁷ cm⁻³ and equal to or less than 1 × 10²¹ cm⁻³. In addition, the p-type impurity concentration of the transistor base region 33 is defined as a p-type impurity concentration at a position half the depth of the transistor base region 33.

The depth of the transistor base region 33 is, for example, equal to or more than 0.3 μm and equal to or less than 1.0 μm.

The transistor base region 33 is electrically connected to the source electrode 41. The transistor base region 33 is in contact with, for example, the source electrode 41. The transistor base region 33 is fixed to the electric potential of the source electrode 41.

The n⁺-type source region 34 is provided in the transistor region 10. The source region 34 is provided between the transistor base region 33 and the source electrode 41. The source region 34 is provided between the transistor base region 33 and the first face F1. The source region 34 extends, for example, in the first direction.

The source region 34 contains, for example, phosphorus (P) as an n-type impurity. The n-type impurity concentration of the source region 34 is higher than the n-type impurity concentration of the drift region 32.

The n-type impurity concentration of the source region 34 is, for example, equal to or more than 1 × 10¹⁸ cm⁻³ and equal to or less than 1 × 10²¹ cm⁻³. The depth of the source region 34 is smaller than the depth of the transistor base region 33. The depth of the source region 34 is, for example, equal to or more than 0.1 μm and equal to or less than 0.3 μm.

The source region 34 is electrically connected to the source electrode 41. The source region 34 is in contact with, for example, the source electrode 41. The source region 34 is fixed to the electric potential of the source electrode 41.

The p-type diode base region 35 is provided in the diode region 20. The diode base region 35 is provided between the drift region 32 and the source electrode 41. The diode base region 35 is provided between the drift region 32 and the first face F1. The diode base region 35 is provided on the drift region 32.

The diode base region 35 extends in the second direction. The diode base region 35 is repeatedly arranged in the first direction.

The diode base region 35 functions as a p-type semiconductor region of the pn junction diode.

The diode base region 35 contains, for example, aluminum (Al) as a p-type impurity. The p-type impurity concentration of the diode base region 35 is, for example, equal to or more than 5 × 10¹⁷ cm⁻³ and equal to or less than 1 × 10²¹ cm⁻³. In addition, the p-type impurity concentration of the diode base region 35 is defined as a p-type impurity concentration at a position half the depth of the diode base region 35.

The depth of the diode base region 35 is, for example, equal to or more than 0.3 μ m and equal to or less than 1.0 μm.

The p-type impurity concentration of the diode base region 35 is, for example, substantially equal to the p-type impurity concentration of the transistor base region 33. The depth of the diode base region 35 is, for example, substantially equal to the depth of the transistor base region 33.

The diode base region 35 is electrically connected to the source electrode 41. The diode base region 35 is in contact with, for example, the source electrode 41. The diode base region 35 is fixed to the electric potential of the source electrode 41.

The first gate electrode 51 and the second gate electrode 52 are provided on the first face F1 side of the silicon carbide layer 30. The first gate electrode 51 and the second gate electrode 52 face the transistor base region 33. The first gate electrode 51 and the second gate electrode 52 face, for example, a portion of the transistor base region 33 in contact with the first face F1. The first gate electrode 51 and the second gate electrode 52 extend in the second direction. The first gate electrode 51 and the second gate electrode 52 are arranged in parallel to each other.

The first gate electrode 51 and the second gate electrode 52 are conductive layers. The first gate electrode 51 is, for example, a polycrystalline silicon containing p-type impurities or n-type impurities.

The gate insulating layer 54 is provided between the first gate electrode 51 and the silicon carbide layer 30 and between the second gate electrode 52 and the silicon carbide layer 30. The gate insulating layer 54 is provided between the first gate electrode 51 and the transistor base region 33 and between the second gate electrode 52 and the transistor base region 33. The gate insulating layer 54 is provided between the first gate electrode 51 and the drift region 32 and between the second gate electrode 52 and the drift region 32.

The gate insulating layer 54 is, for example, a silicon oxide. For example, a high-k insulating material (insulating material with a high dielectric constant) can be applied to the gate insulating layer 54.

The interlayer insulating layer 55 is provided on the first gate electrode 51, the second gate electrode 52, and the silicon carbide layer 30. The interlayer insulating layer 55 is provided between the first gate electrode 51 and the source electrode 41 and between the second gate electrode 52 and the source electrode 41. The interlayer insulating layer 55 is, for example, a silicon oxide.

The interlayer insulating layer 55 has a function of electrically isolating the first gate electrode 51 from the source electrode 41 and electrically isolating the second gate electrode 52 from the source electrode 41.

The source electrode 41 is provided on the first face F1 side of the silicon carbide layer 30. The source electrode 41 is in contact with the first face F1.

The source electrode 41 is electrically connected to the drift region 32, the transistor base region 33, the source region 34, and the diode base region 35. The source electrode 41 is in contact with, for example, the drift region 32, the transistor base region 33, the source region 34, and the diode base region 35.

The source electrode 41 contains metal. The metal forming the source electrode 41 is, for example, a stacked structure of titanium (Ti) and aluminum (Al).

The portion of the source electrode 41 in contact with the transistor base region 33, the source region 34, and the diode base region 35 is, for example, a metal silicide. The metal silicide is, for example, a titanium silicide or a nickel silicide.

For example, no metal silicide is provided in the portion of the source electrode 41 in contact with the drift region 32.

The contact between each of the transistor base region 33, the source region 34, and the diode base region 35 and the source electrode 41 is, for example, an ohmic contact. The contact between the drift region 32 and the source electrode 41 is, for example, a Schottky contact.

The drain electrode 42 is provided on the second face F2 side of the silicon carbide layer 30. The drain electrode 42 is in contact with the second face F2. The drain electrode 42 is in contact with the drain region 31.

The drain electrode 42 is, for example, a metal or a metal semiconductor compound. The drain electrode 42 contains at least one material selected from a group consisting of nickel silicide, titanium (Ti), nickel (Ni), silver (Ag), and gold (Au), for example.

The contact between the drain region 31 and the drain electrode 42 is, for example, an ohmic contact.

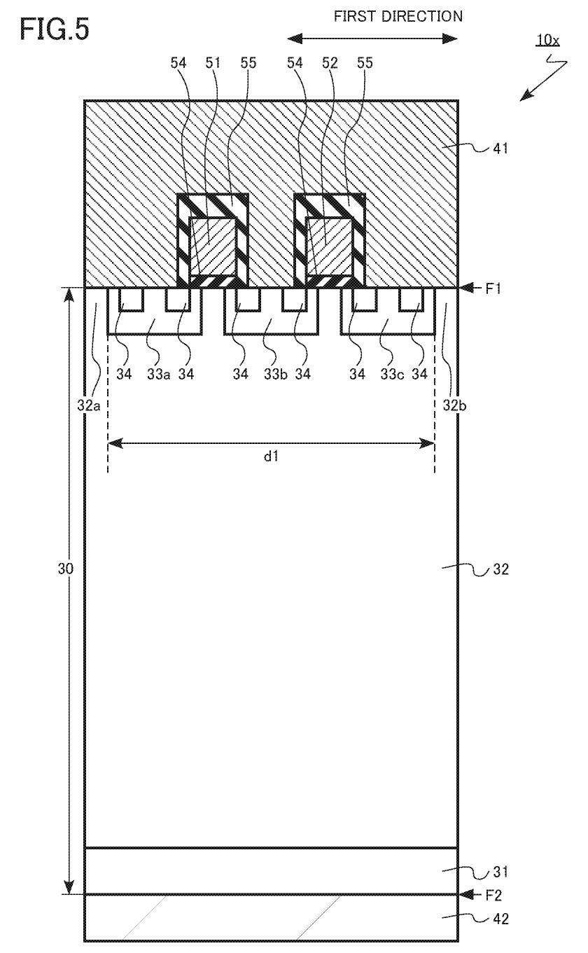

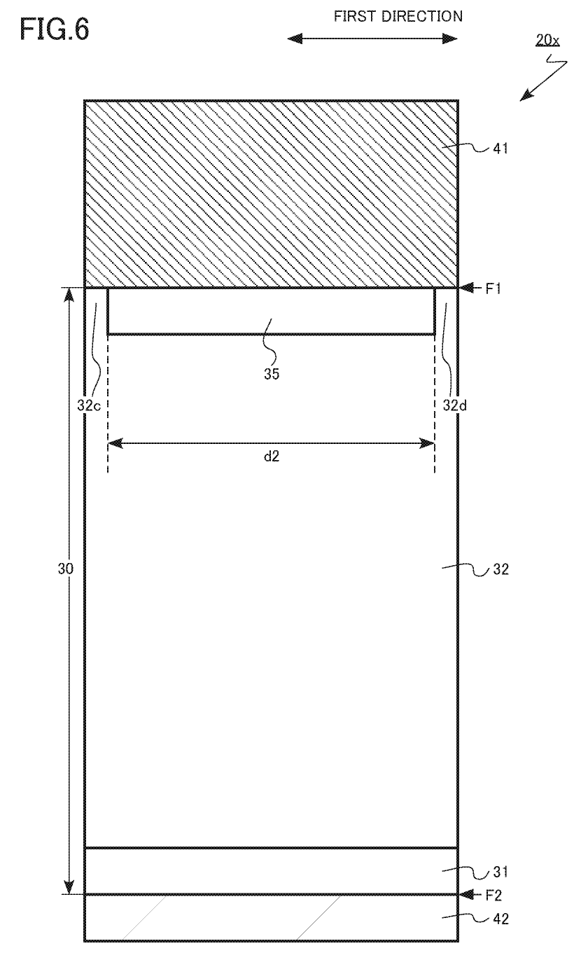

FIGS. 5 and 6 are schematic cross-sectional views of a part of the semiconductor device according to the first embodiment. FIG. 5 is a diagram showing a cross section of the transistor unit 10x. FIG. 6 is a diagram showing a cross section of the diode unit 20x.

The transistor unit 10x includes a silicon carbide layer 30, a source electrode 41 (first electrode), a drain electrode 42 (second electrode), a first gate electrode 51, a second gate electrode 52, a gate insulating layer 54, and an interlayer insulating layer 55.

The silicon carbide layer 30 of the transistor unit 10x includes an n⁺-type drain region 31, an n⁻ -type drift region 32 (first silicon carbide region), a first transistor base region of p-type 33a (second silicon carbide region), a second transistor base region of p-type 33b (third silicon carbide region), a third transistor base region of p-type 33c (sixth silicon carbide region), and an n⁺-type source region 34 (fourth silicon carbide region).

The drift region 32 includes a first portion 32a and a second portion 32b. The first transistor base region 33a, the second transistor base region 33b, and the third transistor base region 33c are each one of the transistor base regions 33.

The first portion 32a and the second portion 32b are in contact with the source electrode 41. The first portion 32a and the second portion 32b are in contact with the first face F1. The first portion 32a and the second portion 32b extend in the second direction on the first face F1. The second portion 32b is provided in the first direction with respect to the first portion 32a.

The first portion 32a and the second portion 32b are electrically connected to the source electrode 41. The contact between each of the first portion 32a and the second portion 32b and the source electrode 41 is, for example, a Schottky contact. The first portion 32a and the second portion 32b function as n-type semiconductor regions of the SBD.

The distance between the first portion 32a and the second portion 32b in the first direction is a first distance d1.

The first transistor base region of p-type 33a is provided between the first portion 32a and the second portion 32b. The first transistor base region 33a extends in the second direction.

The second transistor base region of p-type 33b is provided between the first transistor base region 33a and the second portion 32b. The second transistor base region 33b extends in the second direction. The second transistor base region 33b is spaced from the first transistor base region 33a.

The third transistor base region of p-type 33c is provided between the second transistor base region 33b and the second portion 32b. The third transistor base region 33c extends in the second direction. The third transistor base region 33c is spaced from the second transistor base region 33b.

The transistor unit 10x includes the first gate electrode 51 and the second gate electrode 52. The first gate electrode 51 faces the first transistor base region 33a and the second transistor base region 33b. The second gate electrode 52 faces the second transistor base region 33b and the third transistor base region 33c.

The gate insulating layer 54 is provided between the first gate electrode 51 and each of the first transistor base region 33a and the second transistor base region 33b. The gate insulating layer 54 is provided between the second gate electrode 52 and each of the second transistor base region 33b and the third transistor base region 33c.

Parts of the first transistor base region 33a, the second transistor base region 33b, and the third transistor base region 33c function as channel regions of the MOSFET 100.

A MOSFET and an SBD are provided in the transistor unit 10x.

The diode unit 20x includes a silicon carbide layer 30, a source electrode 41 (first electrode), and a drain electrode 42 (second electrode).

The silicon carbide layer 30 of the diode unit 20x includes an n⁺-type drain region 31, an n⁻ -type drift region 32 (first silicon carbide region), and a p-type diode base region 35 (fifth silicon carbide region).

The drift region 32 includes a third portion 32c and a fourth portion 32d.

The third portion 32c and the fourth portion 32d are in contact with the source electrode 41. The third portion 32c and the fourth portion 32d are in contact with the first face F1. The third portion 32c and the fourth portion 32d extend in the second direction on the first face F1. The fourth portion 32d is provided in the first direction with respect to the third portion 32c.

The third portion 32c and the fourth portion 32d are electrically connected to the source electrode 41. The contact between each of the third portion 32c and the fourth portion 32d and the source electrode 41 is, for example, a Schottky contact. The third portion 32c and the fourth portion 32d function as n-type semiconductor regions of the SBD.

The distance between the third portion 32c and the fourth portion 32d in the first direction is a second distance d2. The second distance d2 is equal to the first distance d1.

The p-type diode base region 35 is provided between the third portion 32c and the fourth portion 32d. The diode base region 35 extends in the second direction. The diode base region 35 functions as a p-type semiconductor region of the pn junction diode.

A pn junction diode and an SBD are provided in the diode unit 20x. The occupied area of a region when projecting the pn junction diode onto the first face F1 in the diode unit 20x is larger than the occupied area of a region when projecting the pn junction diode onto the first face F1 in the transistor unit 10x.

In the diode unit 20x, the area of contact between the source electrode 41 and the silicon carbide layer 30 is larger than the area of contact between the source electrode 41 and the silicon carbide layer 30 in the transistor unit 10x. In the diode unit 20x, the area of contact between the source electrode 41 and the first face F1 of the silicon carbide layer 30 is larger than the area of contact between the source electrode 41 and the first face F1 of the silicon carbide layer 30 in the transistor unit 10x. In the diode unit 20x, the area of contact between the source electrode 41 and the diode base region 35 is larger than the area of contact between the source electrode 41 and the transistor base region 33 in the transistor unit 10x.

Next, the function and effect of the MOSFET 100 according to the first embodiment will be described.

A MOSFET and an SBD are provided in the MOSFET 100 according to the first embodiment.

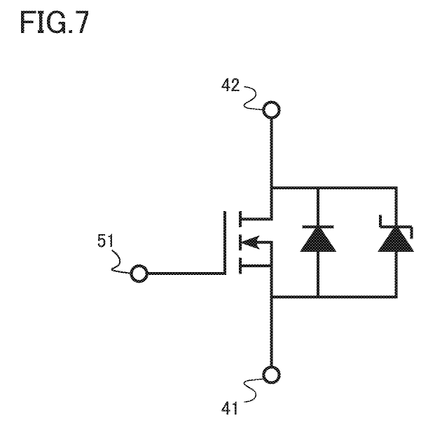

FIG. 7 is an equivalent circuit diagram of the semiconductor device according to the first embodiment. Between the source electrode 41 and the drain electrode 42, a pn junction diode and an SBD are connected as built-in diodes in parallel with a transistor.

For example, a case where the MOSFET 100 is used as a switching element connected to an inductive load is considered. When the MOSFET 100 is off, a voltage that makes the source electrode 41 positive with respect to the drain electrode 42 may be applied by the load current due to the inductive load. In this case, a forward current flows through the built-in diode. This state is also referred to as a reverse conduction state. The current flowing through the built-in diode is referred to as a freewheeling current.

A forward voltage (Vf) at which a forward current starts to flow through the SBD is lower than a forward voltage (Vf) of the pn junction diode. Therefore, first, a forward current flows through the SBD.

The forward voltage (Vf) of the SBD is, for example, 1.0 V. The forward voltage (Vf) of the pn junction diode is, for example, 2.5 V.

If the SBD is not provided in the MOSFET, a forward current flows through the pn junction diode in the reverse conduction state. When a forward current is made to flow by using a pn junction diode, a stacking fault grows in the silicon carbide layer due to the recombination energy of carriers, which causes a problem of increasing the on-resistance of the MOSFET. The increase in the on-resistance of the MOSFET leads to a reduction in the reliability of the MOSFET.

The SBD operates in a unipolar manner. Therefore, even if a forward current flows, no stacking fault grows in the silicon carbide layer 30 due to the recombination energy of carriers. Therefore, the reliability of the MOSFET 100 is improved by providing the SBD as a built-in diode.

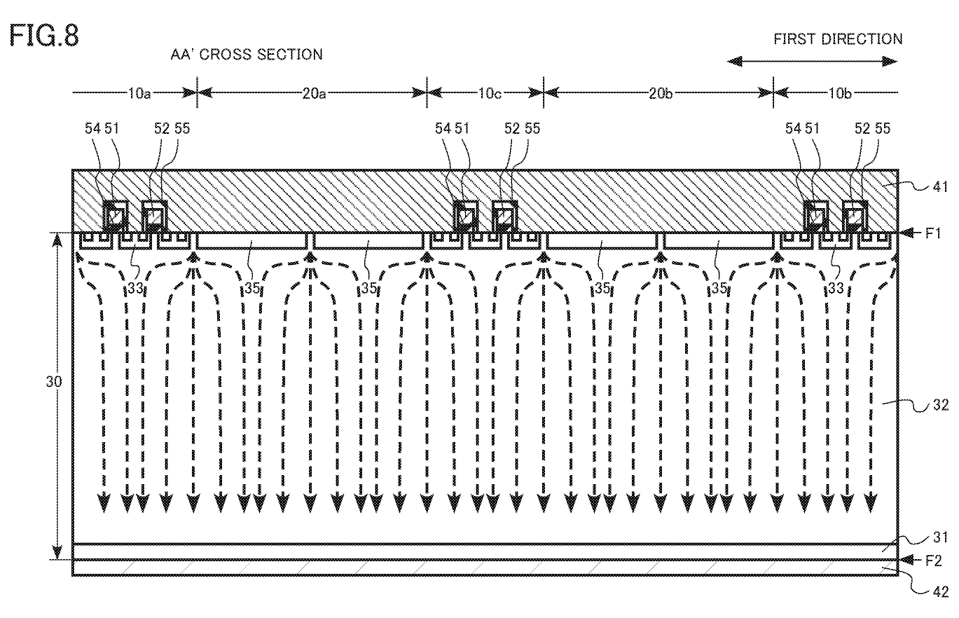

FIG. 8 is an explanatory diagram of the function and effect of the semiconductor device according to the first embodiment. FIG. 8 is a diagram corresponding to FIG. 3.

FIG. 8 is a diagram showing a current flowing through a built-in diode of the MOSFET 100 according to the first embodiment. FIG. 8 shows a state in which a forward current flows only through the SBD. That is, FIG. 8 shows a state in which a voltage applied across the pn junction of the pn junction diode is lower than the forward voltage (Vf) of the pn junction diode.

In FIG. 8, the dotted arrow indicates the current flowing through the SBD. As shown in FIG. 8, the current flowing through the SBD flows around the bottoms of the transistor base region 33 and the diode base region 35. For this reason, an electrostatic potential flow-around occurs in the drift region 32 facing the bottom of the transistor base region 33 and the bottom of the diode base region 35. Due to the electrostatic potential flow-around, the voltage applied between the transistor base region 33 and the drift region 32 and between the diode base region 35 and the drift region 32 is reduced.

Therefore, at the bottom of the transistor base region 33 and the bottom of the diode base region 35, the forward voltage (Vf) of the pn junction diode is less likely to be exceeded. In other words, by providing the SBD, the forward voltage (Vf) of the pn junction diode of the MOSFET 100 can be made higher than that when the SBD is not provided. Therefore, since the bipolar operation of the pn junction diode is suppressed, the formation of a stacking fault in the silicon carbide layer 30 due to the recombination energy of carriers is suppressed.

The forward voltage (Vf) of the pn junction diode of the MOSFET 100 depends on the distance between two SBDs adjacent to each other in the first direction. In the MOSFET 100, the distance (first distance d1) between two SBDs in the transistor region 10 is equal to the distance (second distance d2) between two SBDs in the diode region 20. Therefore, the forward voltage (Vf) of the pn junction diode in the transistor region 10 and the forward voltage (Vf) of the pn junction diode in the diode region 20 are equal.

A high surge voltage may be applied to the MOSFET, exceeding the steady state instantaneously. A surge current flows according to the surge voltage. The surge current flows from the source electrode 41 to the drain electrode 42.

When a large surge current flows, the MOSFET generates heat, and as a result, the MOSFET breaks down. The maximum allowable peak current value (I_{FSM}) of the surge current allowed in the MOSFET is referred to as a surge current withstand capacity. In a MOSFET in which the SBD is provided, it is desired to improve the surge current withstand capacity.

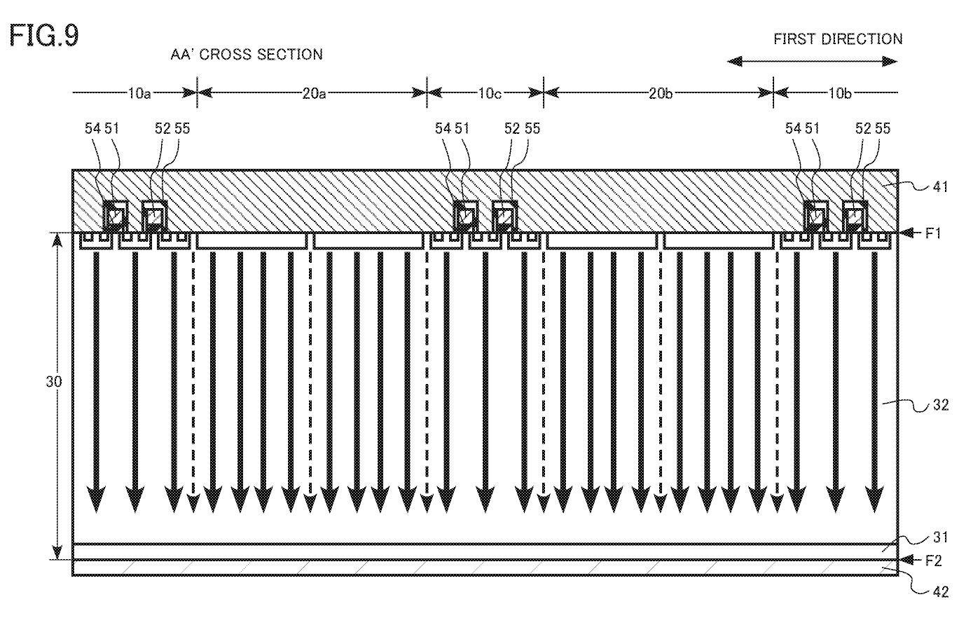

FIG. 9 is an explanatory diagram of the function and effect of the semiconductor device according to the first embodiment. FIG. 9 is a diagram corresponding to FIG. 3.

FIG. 9 is a diagram showing a current flowing through the built-in diode of the MOSFET 100 according to the first embodiment. FIG. 9 shows a state in which a forward current flows through the SBD and the pn junction diode. That is, FIG. 9 shows a state in which a voltage applied across the pn junction of the pn junction diode is higher than the forward voltage (Vf) of the pn junction diode.

In FIG. 9, the dotted arrow indicates a current flowing through the SBD, and the solid arrow indicates a current flowing through the pn junction diode.

When a high surge voltage is applied to the MOSFET 100, the voltage applied across the pn junction of the pn junction diode becomes higher than the forward voltage (Vf) of the pn junction diode. When the voltage applied across the pn junction of the pn junction diode becomes higher than the forward voltage (Vf) of the pn junction diode, a current also flows through the pn junction diode, as shown in FIG. 9.

In the MOSFET 100, the diode region 20 is provided between the transistor regions 10. As described above, the occupied area of a region when projecting the pn junction diode onto the first face F1 in the diode unit 20x is larger than the occupied area of a region when projecting the pn junction diode onto the first face F1 in the transistor unit 10x. Therefore, by providing the diode region 20 in the MOSFET 100, the occupied area of the pn junction diode in the entire MOSFET 100 is increased. Therefore, in the MOSFET 100, a surge current that can flow when a high surge voltage is applied is larger than that when the diode region 20 is not provided.

In addition, the occupied area of the pn junction diode of the diode unit 20x is larger than the occupied area of the pn junction diode of the transistor unit 10x. Therefore, when a high surge voltage is applied, conductivity modulation in the diode unit 20x proceeds ahead of conductivity modulation in the transistor unit 10x. The conductivity modulation that starts in the diode unit 20x propagates to the transistor unit 10x, thereby promoting the conductivity modulation of the transistor unit 10x. For this reason, the increase rate of the surge current flowing through MOSFET 100 is larger than that when the diode region 20 is not provided. Therefore, in the MOSFET 100, a surge current that can flow when a high surge voltage is applied is larger than that when the diode region 20 is not provided.

As a result, the surge current withstand capacity of the MOSFET 100 is improved.

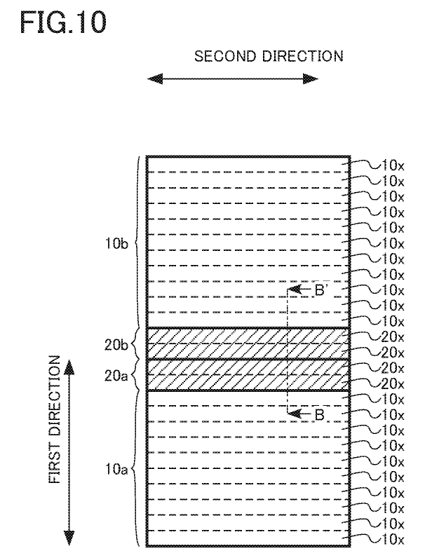

FIG. 10 is a schematic top view of a part of a semiconductor device according to a comparative example. FIG. 10 is a diagram corresponding to FIG. 2 in the first embodiment.

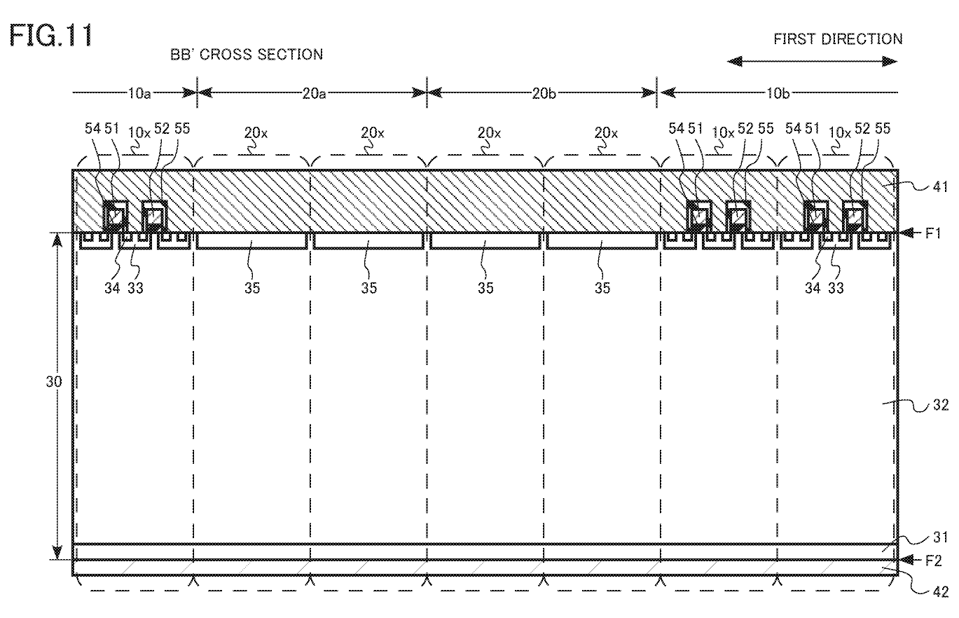

FIG. 11 is a schematic cross-sectional view of a part of the semiconductor device according to the comparative example. FIG. 11 is a diagram showing a cross section taken along the line BB' of FIG. 10. FIG. 11 is a diagram corresponding to FIG. 3 in the first embodiment.

A MOSFET according to the comparative example is different from the MOSFET 100 according to the first embodiment in that the MOSFET according to the comparative example does not include the third transistor region 10c.

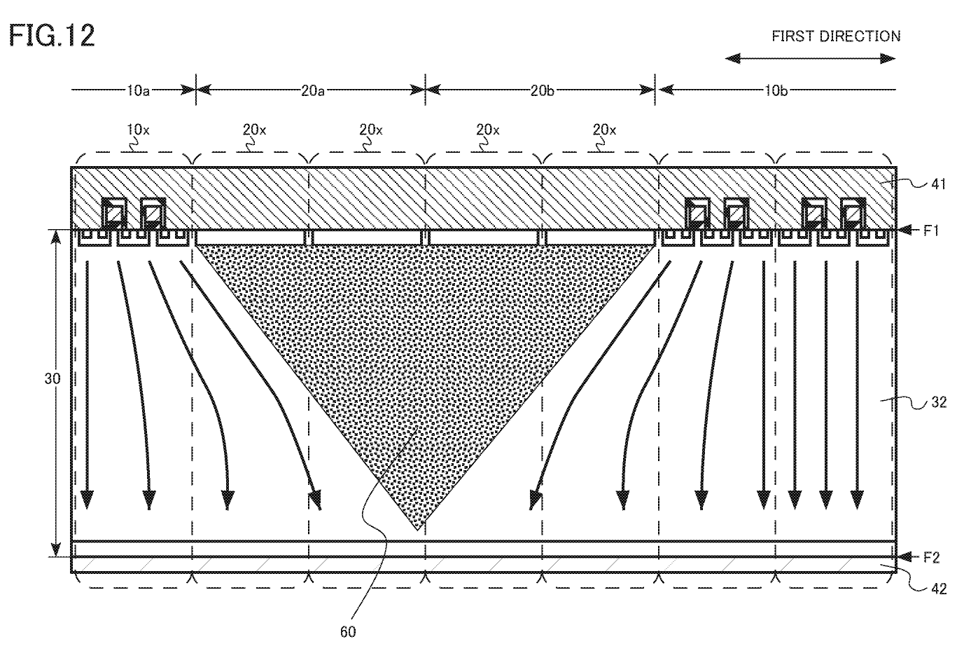

FIG. 12 is a diagram showing a problem of the semiconductor device according to the comparative example. FIG. 12 is a diagram corresponding to FIG. 11.

FIG. 12 is a diagram showing a current flowing through a transistor in the MOSFET according to the comparative example. FIG. 12 shows a state in which an on-current flows through the transistor in the transistor region 10.

In FIG. 12, the solid arrow indicates an on-current flowing through the transistor. Since no transistor is present in the diode region 20, the on-current per unit area is reduced compared to a MOSFET in which the diode region 20 is not provided. In other words, the on-resistance per unit area of the MOSFET increases.

However, as shown in FIG. 12, a part of the on-current flows from the transistor regions 10 on both sides of the diode region 20 into the drift region 32 of the diode region 20. For this reason, the increase in the on-resistance per unit area caused by providing the diode region 20 is reduced.

In the MOSFET according to the comparative example, an ineffective region 60 shown in FIG. 12 is a region where the on-current of the transistor does not flow.

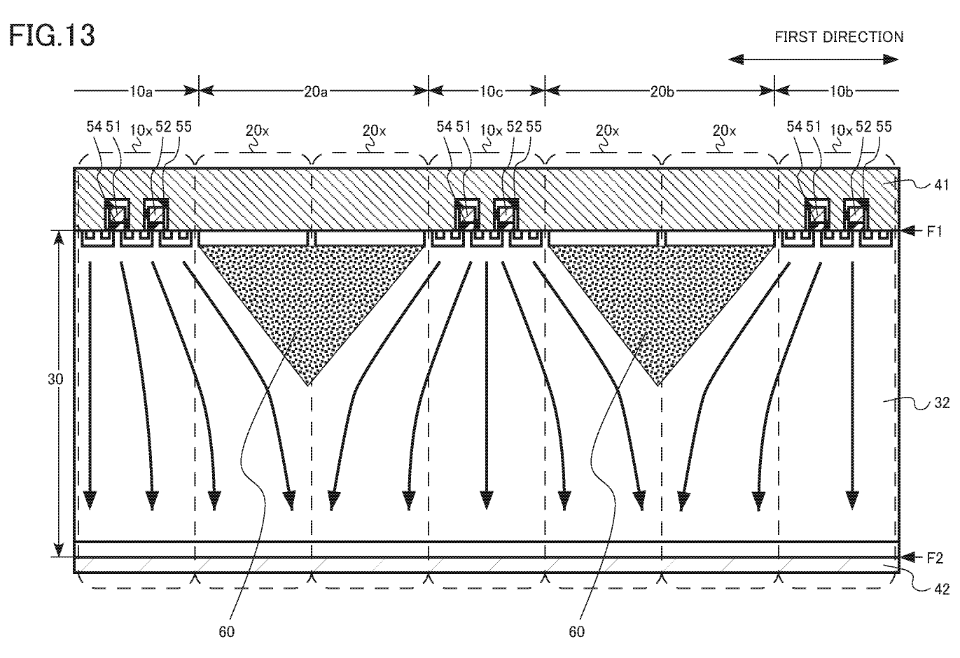

FIG. 13 is a diagram illustrating the function and effect of the semiconductor device according to the first embodiment. FIG. 13 is a diagram corresponding to FIG. 3.

FIG. 13 is a diagram showing a current flowing through the transistor of the MOSFET 100 according to the first embodiment. FIG. 13 shows a state in which an on-current flows through the transistor in the transistor region 10.

In the MOSFET 100 according to the first embodiment, the third transistor region 10c is provided between the first diode region 20a and the second diode region 20b, unlike in the MOSFET according to the comparative example. For this reason, as shown in FIG. 13, the total volume of the ineffective region 60 where the on-current of the transistor does not flow is reduced compared to the MOSFET according to the comparative example. Therefore, compared to the MOSFET according to the comparative example, the increase in the on-resistance per unit area caused by providing the diode region 20 is further reduced. As a result, it is possible to realize a MOSFET with reduced on-resistance per unit area.

The third transistor region 10c includes one transistor unit 10x. If the number of transistor units 10x included in the third transistor region 10c is equal to or more than two, a decrease in surge current withstand capacity becomes noticeable.

When the distance between the first diode region 20a and the second diode region 20b is short, conductivity modulation in the MOSFET is promoted by the interaction between conductivity modulation occurring in the first diode region 20a and the conductivity modulation occurring in the second diode region 20b when a surge current flows. Therefore, a surge current that can flow when a high surge voltage is applied increases to improve the surge current withstand capacity of the MOSFET.

When the number of transistor units 10x included in the third transistor region 10c is equal to or more than two, the distance between the first diode region 20a and the second diode region 20b increases. When the distance between the first diode region 20a and the second diode region 20b increases, the conductivity modulation interaction between the first diode region 20a and the second diode region 20b when a surge current flows is less likely to occur. Therefore, a surge current that can flow when a high surge voltage is applied decreases to lower the surge current withstand capacity of the MOSFET.

In the MOSFET 100 according to the first embodiment, by limiting the number of transistor units 10x included in the third transistor region 10c to one, it is possible to minimize the decrease in surge current withstand capacity even when the third transistor region 10c is provided.

According to the MOSFET 100 according to the first embodiment, it is possible to improve the surge current withstand capacity and reduce the on-resistance.

### First Modification Example

A semiconductor device according to a first modification example is different from the semiconductor device according to the first embodiment in that the first diode region includes three diode units and the second diode region includes three diode units.

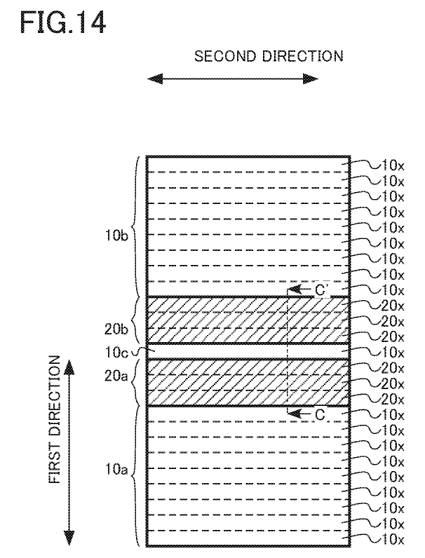

FIG. 14 is a schematic top view of a part of the semiconductor device according to the first modification example of the first embodiment. FIG. 14 corresponds to FIG. 2 in the first embodiment.

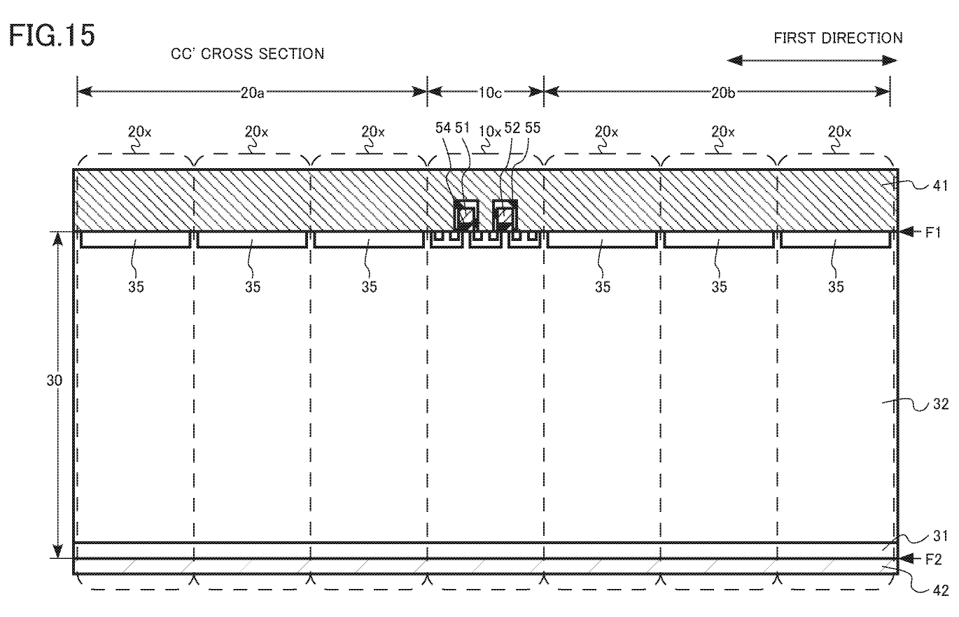

FIG. 15 is a schematic cross-sectional view of a part of the semiconductor device according to the first modification example of the first embodiment. FIG. 15 is a diagram showing a cross section taken along the line CC' of FIG. 14.

A MOSFET according to the first modification example of the first embodiment includes a first transistor region 10a, a second transistor region 10b, and a third transistor region 10c. In addition, the MOSFET according to the first modification example includes a first diode region 20a and a second diode region 20b.

The transistor region 10 includes a transistor unit 10x. In addition, the diode region 20 includes a diode unit 20x.

The first transistor region 10a includes, for example, nine transistor units 10x. The second transistor region 10b includes, for example, nine transistor units 10x.

The first diode region 20a includes three diode units 20x. The second diode region 20b includes three diode units 20x.

According to the MOSFET according to the first modification example of the first embodiment, as in the first embodiment, it is possible to improve the surge current withstand capacity and reduce the on-resistance.

### Second Modification Example

A semiconductor device according to a second modification example is different from the semiconductor device according to the first embodiment in that the first diode region includes one diode unit and the second diode region includes one diode unit.

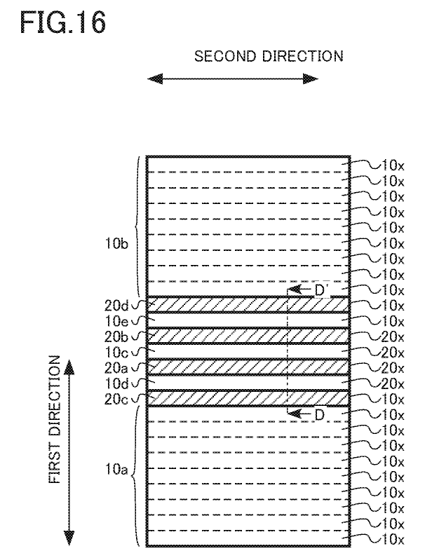

FIG. 16 is a schematic top view of a part of a semiconductor device according to the second modification example of the first embodiment. FIG. 16 corresponds to FIG. 2 in the first embodiment.

The MOSFET according to the second modification example of the first embodiment includes a first transistor region 10a, a second transistor region 10b, a third transistor region 10c, a fourth transistor region 10d, and a fifth transistor region 10e. In addition, the MOSFET according to the second modification example includes a first diode region 20a, a second diode region 20b, a third diode region 20c, and a fourth diode region 20d.

The transistor region 10 includes a transistor unit 10x. In addition, the diode region 20 includes a diode unit 20x.

The fourth transistor region 10d is provided between the first transistor region 10a and the third transistor region 10c. The fifth transistor region 10e is provided between the third transistor region 10c and the second transistor region 10b.

The first diode region 20a is provided between the third transistor region 10c and the fourth transistor region 10d. The second diode region 20b is provided between the third transistor region 10c and the fifth transistor region 10e. The third diode region 20c is provided between the first transistor region 10a and the fourth transistor region 10d. The fourth diode region 20d is provided between the second transistor region 10b and the fifth transistor region 10e.

The first transistor region 10a includes, for example, nine transistor units 10x. The second transistor region 10b includes, for example, nine transistor units 10x. The third transistor region 10c, the fourth transistor region 10d, and the fifth transistor region 10e each include one transistor unit 10x.

Each of the first diode region 20a, the second diode region 20b, the third diode region 20c, and the fourth diode region 20d includes one diode unit 20x.

According to the MOSFET according to the second modification example of the first embodiment, as in the first embodiment, it is possible to improve the surge current withstand capacity and reduce the on-resistance.

As described above, according to the first embodiment and its modification example, it is possible to provide a semiconductor device with improved surge current withstand capacity and reduced on-resistance.

### Second Embodiment

A semiconductor device according to a second embodiment is different from the semiconductor device according to the first embodiment in that the transistor unit does not include a second gate electrode and a sixth silicon carbide region. Hereinafter, the description of a part of the content overlapping the first embodiment may be omitted.

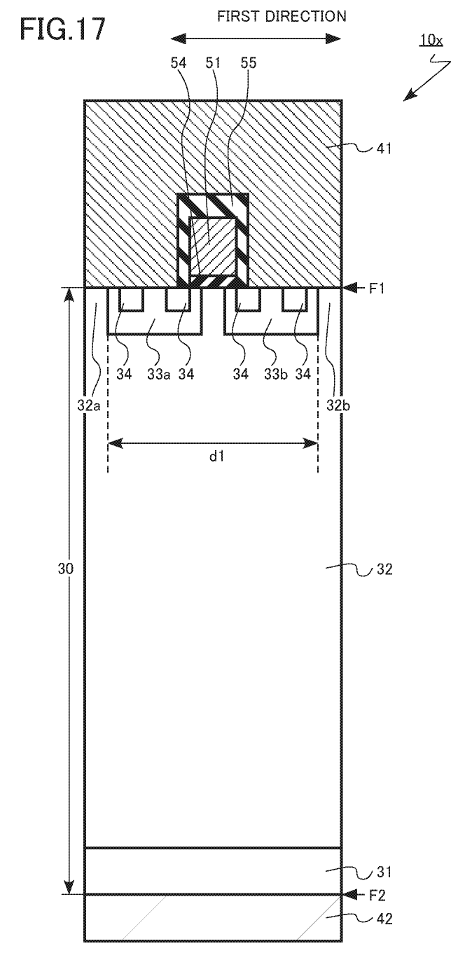

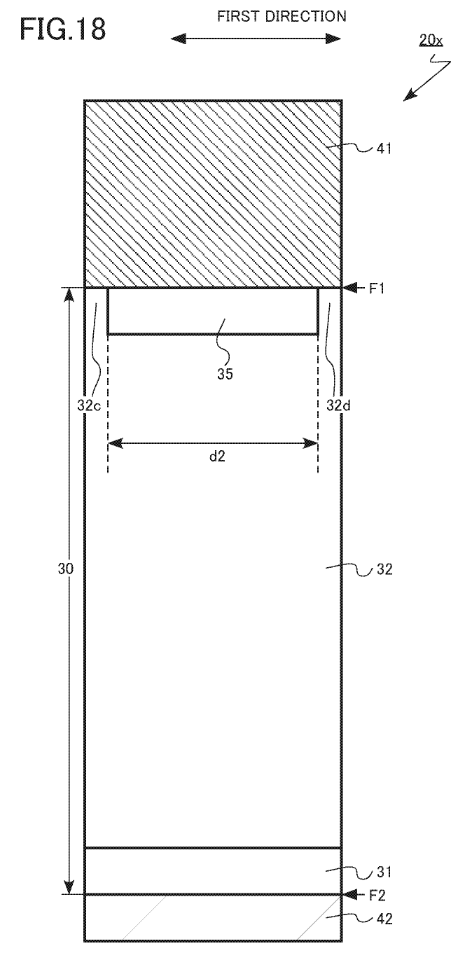

FIGS. 17 and 18 are schematic cross-sectional views of a part of the semiconductor device according to the second embodiment. FIG. 17 is a diagram showing a cross section of a transistor unit 10x. FIG. 18 is a diagram showing a cross section of a diode unit 20x. FIG. 17 is a diagram corresponding to FIG. 5 in the first embodiment. FIG. 18 is a diagram corresponding to FIG. 6 in the first embodiment.

The transistor unit 10x includes a silicon carbide layer 30, a source electrode 41 (first electrode), a drain electrode 42 (second electrode), a first gate electrode 51, a gate insulating layer 54, and an interlayer insulating layer 55.

The silicon carbide layer 30 of the transistor unit 10x includes an n⁺-type drain region 31, an n⁻-type drift region 32 (first silicon carbide region), a first transistor base region of p-type 33a (second silicon carbide region), a second transistor base region of p-type 33b (third silicon carbide region), and an n⁺-type source region 34 (fourth silicon carbide region).

The drift region 32 includes a first portion 32a and a second portion 32b. The distance between the first portion 32a and the second portion 32b in the first direction is a first distance d1.

The diode unit 20x includes a silicon carbide layer 30, a source electrode 41 (first electrode), and a drain electrode 42 (second electrode).

The silicon carbide layer 30 of the diode unit 20x includes an n⁺-type drain region 31, an n⁻ -type drift region 32 (first silicon carbide region), and a p-type diode base region 35 (fifth silicon carbide region).

The drift region 32 includes a third portion 32c and a fourth portion 32d. The distance between the third portion 32c and the fourth portion 32d in the first direction is a second distance d2. The second distance d2 is equal to the first distance d1.

As described above, according to the second embodiment, as in the first embodiment, it is possible to provide a semiconductor device with improved surge current withstand capacity and reduced on-resistance.

### Third Embodiment

A semiconductor device according to a third embodiment is different from the semiconductor device according to the first embodiment in that the transistor region further includes: a seventh silicon carbide region of a second conductive type that is provided between the first silicon carbide region and the first electrode, is electrically connected to the first electrode, extends in the second direction, is provided between the sixth silicon carbide region and the second portion in the first direction, and is spaced from the sixth silicon carbide region; and a third gate electrode that faces the sixth silicon carbide region and the seventh silicon carbide region and extends in the second direction. Hereinafter, the description of a part of the content overlapping the first embodiment may be omitted.

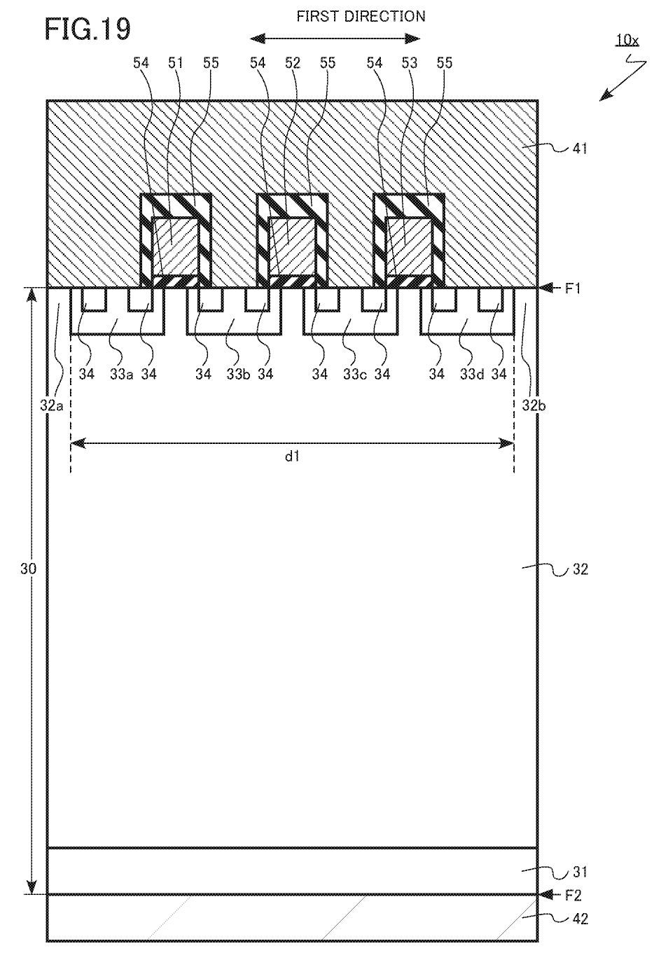

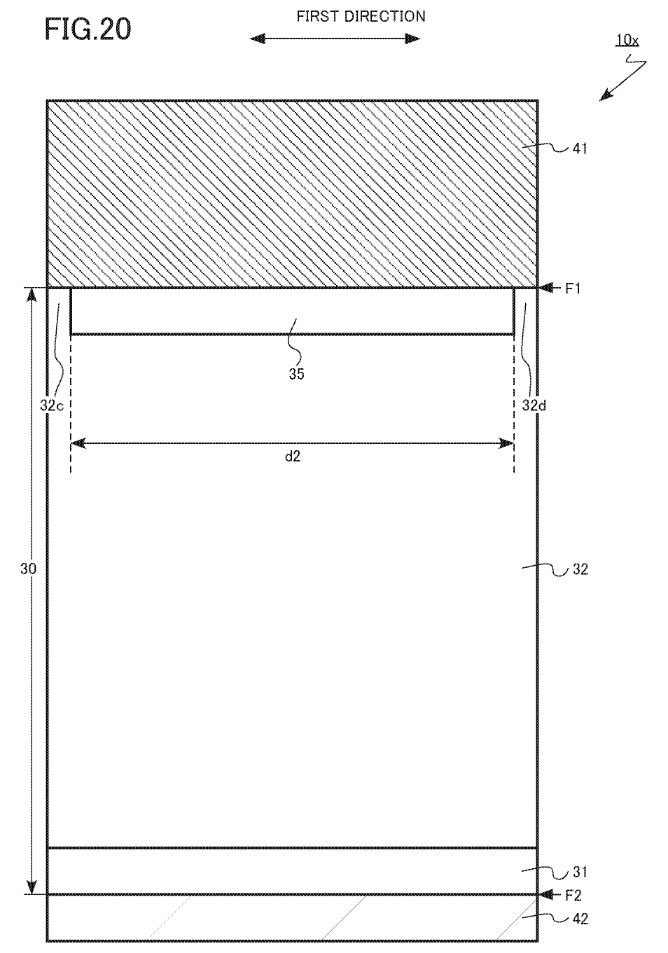

FIGS. 19 and 20 are schematic cross-sectional views of a part of the semiconductor device according to the third embodiment. FIG. 19 is a diagram showing a cross section of a transistor unit 10x. FIG. 20 is a diagram showing a cross section of a diode unit 20x. FIG. 19 is a diagram corresponding to FIG. 5 in the first embodiment. FIG. 20 is a diagram corresponding to FIG. 6 in the first embodiment.

The transistor unit 10x includes a silicon carbide layer 30, a source electrode 41 (first electrode), a drain electrode 42 (second electrode), a first gate electrode 51, a second gate electrode 52, a third gate electrode 53, a gate insulating layer 54, and an interlayer insulating layer 55.

The silicon carbide layer 30 of the transistor unit 10x includes an n⁺-type drain region 31, an n⁻-type drift region 32 (first silicon carbide region), a first transistor base region of p-type 33a (second silicon carbide region), a second transistor base region of p-type 33b (third silicon carbide region), a third transistor base region of p-type 33c (sixth silicon carbide region), a fourth transistor base region of p-type 33d (seventh silicon carbide region), and an n⁺-type source region 34 (fourth silicon carbide region).

The fourth transistor base region of p-type 33d is provided between the third transistor base region 33c and the second portion 32b. The fourth transistor base region 33d extends in the second direction. The fourth transistor base region 33d is spaced from the third transistor base region 33c.

The transistor unit 10x includes a first gate electrode 51, a second gate electrode 52, and a third gate electrode 53. The third gate electrode 53 faces the third transistor base region 33c and the fourth transistor base region 33d.

The gate insulating layer 54 is provided between the third gate electrode 53 and each of the third transistor base region 33c and the fourth transistor base region 33d.

The diode unit 20x includes a silicon carbide layer 30, a source electrode 41 (first electrode), and a drain electrode 42 (second electrode).

The silicon carbide layer 30 of the diode unit 20x includes an n⁺-type drain region 31, an n⁻-type drift region 32 (first silicon carbide region), and a p-type diode base region 35 (fifth silicon carbide region).

The drift region 32 includes a third portion 32c and a fourth portion 32d. The distance between the third portion 32c and the fourth portion 32d in the first direction is a second distance d2. The second distance d2 is equal to the first distance d1.

As described above, according to the third embodiment, as in the first embodiment, it is possible to provide a semiconductor device with improved surge current withstand capacity and reduced on-resistance.

### Fourth Embodiment

A semiconductor device according to a fourth embodiment is different from the semiconductor device according to the first embodiment in that the diode unit further includes a conductive layer facing the fifth silicon carbide region and extending in the second direction and an insulating layer provided between the conductive layer and the fifth silicon carbide region. Hereinafter, the description of a part of the content overlapping the first embodiment may be omitted.

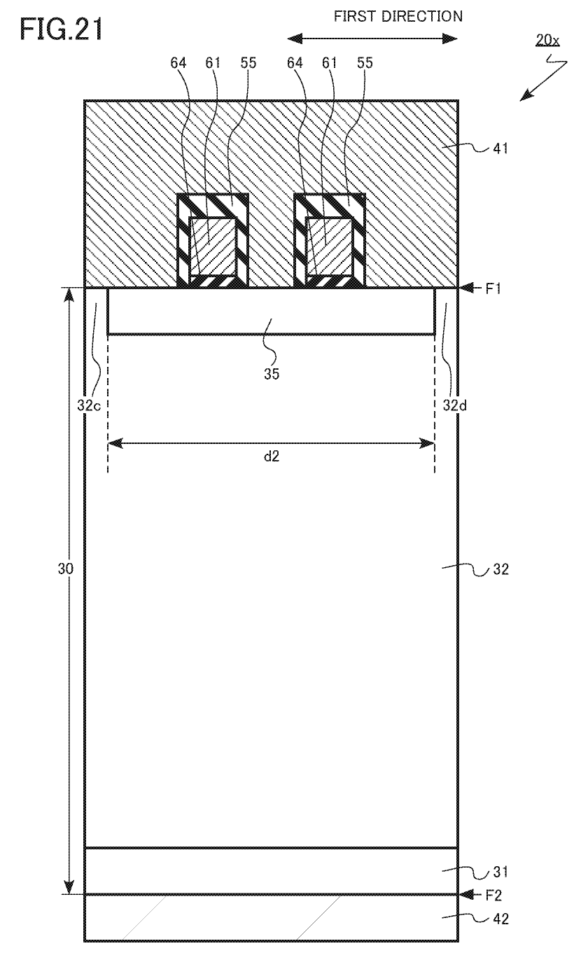

FIG. 21 is a schematic cross-sectional view of a part of the semiconductor device according to the fourth embodiment. FIG. 21 is a diagram showing a cross section of a diode unit 20x. FIG. 21 is a diagram corresponding to FIG. 6 in the first embodiment.

The transistor unit 10x of the MOSFET according to the fourth embodiment has the same configuration as the transistor unit 10x of the MOSFET according to the first embodiment shown in FIG. 5.

The diode unit 20x includes a silicon carbide layer 30, a source electrode 41 (first electrode), a drain electrode 42 (second electrode), a conductive layer 61, an insulating layer 64, and an interlayer insulating layer 55.

The silicon carbide layer 30 of the diode unit 20x includes an n⁺-type drain region 31, an n⁻-type drift region 32 (first silicon carbide region), and a p-type diode base region 35 (fifth silicon carbide region).

The conductive layer 61 is provided on the first face F1 side of the silicon carbide layer 30. The conductive layer 61 faces the diode base region 35. The conductive layer 61 extends in the second direction. The conductive layer 61 has, for example, the same configuration as the first gate electrode 51 and the second gate electrode 52, and is formed simultaneously with the first gate electrode 51 and the second gate electrode 52.

The insulating layer 64 is provided between the conductive layer 61 and the silicon carbide layer 30. The insulating layer 64 is provided between the conductive layer 61 and the diode base region 35. The insulating layer 64 has, for example, the same configuration as the gate insulating layer 54, and is formed simultaneously with the gate insulating layer 54.

The interlayer insulating layer 55 is provided on the conductive layer 61 and the silicon carbide layer 30. The interlayer insulating layer 55 is provided between the conductive layer 61 and the source electrode 41.

The drift region 32 includes a third portion 32c and a fourth portion 32d. The distance between the third portion 32c and the fourth portion 32d in the first direction is a second distance d2. The second distance d2 is equal to the first distance d1.

As described above, according to the fourth embodiment, as in the first embodiment, it is possible to provide a semiconductor device with improved surge current withstand capacity and reduced on-resistance.

In the first to fourth embodiments, the case where the first conductive type is n-type and the second conductive type is p-type has been described as an example. However, the first conductive type can be p-type and the second conductive type can be n-type.

In the first to fourth embodiments, the case of 4H-SiC has been described as an example of the crystal structure of SiC. However, embodiments can also be applied to devices using SiC having other crystal structures, such as 6H-SiC and 3C-SiC. In addition, a face other than the (0001) face can also be applied as the surface of the silicon carbide layer 30.

In the first to fourth embodiments, aluminum (Al) has been exemplified as a p-type impurity, but boron (B) can also be used. In addition, although nitrogen (N) and phosphorus (P) have been exemplified as n-type impurities, arsenic (As), antimony (Sb), and the like can also be applied.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first transistor region including at least one transistor unit;
a second transistor region including at least one transistor unit and provided in a first direction with respect to the first transistor region;
a first diode region provided between the first transistor region and the second transistor region and including at least one diode unit;
a second diode region provided between the first diode region and the second transistor region and including at least one diode unit; and
a third transistor region provided between the first diode region and the second diode region and including one transistor unit,
wherein the transistor unit includes:
a first electrode;
a second electrode;
a first silicon carbide region of a first conductive type provided between the first electrode and the second electrode and including a first portion in contact with the first electrode and extending in a second direction perpendicular to the first direction and a second portion in contact with the first electrode, provided in the first direction with respect to the first portion, and extending in the second direction;
a second silicon carbide region of a second conductive type provided between the first silicon carbide region and the first electrode, electrically connected to the first electrode, extending in the second direction, and provided between the first portion and the second portion in the first direction;
a third silicon carbide region of the second conductive type provided between the first silicon carbide region and the first electrode, electrically connected to the first electrode, extending in the second direction, provided between the second silicon carbide region and the second portion in the first direction, and spaced from the second silicon carbide region;
a fourth silicon carbide region of the first conductive type provided between the second silicon carbide region and the first electrode and electrically connected to the first electrode;
a first gate electrode facing the second silicon carbide region and the third silicon carbide region and extending in the second direction; and
a gate insulating layer provided between the first gate electrode and each of the second silicon carbide region and the third silicon carbide region,
the diode unit includes:
the first electrode;
the second electrode;
the first silicon carbide region including a third portion in contact with the first electrode and extending in the second direction and a fourth portion in contact with the first electrode, provided in the first direction with respect to the third portion, and extending in the second direction; and
a fifth silicon carbide region of the second conductive type provided between the first silicon carbide region and the first electrode, electrically connected to the first electrode, extending in the second direction, and continuously provided between the third portion and the fourth portion in the first direction, and
a first distance between the first portion and the second portion in the first direction is equal to a second distance between the third portion and the fourth portion in the first direction.

2. The semiconductor device according to claim 1,
wherein the at least one diode unit included in the first diode region is equal to or more than two diode units and equal to or less than ten diode units, and
the at least one diode unit included in the second diode region is equal to or more than two diode units and equal to or less than ten diode units.

3. The semiconductor device according to claim 1,
wherein the at least one diode unit included in the first diode region is two diode units, and the at least one diode unit included in the second diode region is two diode units.

4. The semiconductor device according to claim 1,
wherein the at least one diode unit included in the first diode region is one diode unit, and the at least one diode unit included in the second diode region is one diode unit.

5. The semiconductor device according to claim 1,
wherein number of the at least one diode unit included in the first diode region is equal to number of the at least one diode unit included in the second diode region.

6. The semiconductor device according to claim 1,
wherein the at least one transistor unit included in the first transistor region is a plurality of transistor units and the at least one transistor unit included in the second transistor region is a plurality of transistor units.

7. The semiconductor device according to claim 1,
wherein the transistor unit further includes a silicon carbide layer including the first silicon carbide region, the second silicon carbide region, the third silicon carbide region, and the fourth silicon carbide region,
the diode unit further includes the silicon carbide layer including the first silicon carbide region and the fifth silicon carbide region, and
a contact area between the first electrode and the silicon carbide layer in the diode unit is larger than a contact area between the first electrode and the silicon carbide layer in the transistor unit.

8. The semiconductor device according to claim 1,
wherein the third transistor region is in contact with the first diode region and the second diode region.

9. The semiconductor device according to claim 1,
wherein the transistor unit further includes:
a sixth silicon carbide region of the second conductive type provided between the first silicon carbide region and the first electrode, electrically connected to the first electrode, extending in the second direction, provided between the third silicon carbide region and the second portion in the first direction, and spaced from the third silicon carbide region; and
a second gate electrode facing the third silicon carbide region and the sixth silicon carbide region and extending in the second direction.

10. The semiconductor device according to claim 9,
wherein the transistor unit further includes:
a seventh silicon carbide region of the second conductive type provided between the first silicon carbide region and the first electrode, electrically connected to the first electrode, extending in the second direction, provided between the sixth silicon carbide region and the second portion in the first direction, and spaced from the sixth silicon carbide region; and
a third gate electrode facing the sixth silicon carbide region and the seventh silicon carbide region and extending in the second direction.

11. The semiconductor device according to claim 1,
wherein the diode unit further includes:
a conductive layer facing the fifth silicon carbide region and extending in the second direction; and
an insulating layer provided between the conductive layer and the fifth silicon carbide region.

12. The semiconductor device according to claim 1,
wherein the first conductive type is n-type and the second conductive type is p-type.
